(19) United States
(12) Patent Application Publication
(10) Pub. No.: US 2015/0035555 A1
(43) Pub. Date: Feb. 5, 2015

(54) CIRCUIT LIFETIME MEASURING DEVICE AND METHOD

(71) Applicant: REALTEK SEMICONDUCTOR CORPORATION, Hsinchu (TW)

(72) Inventors: Ta-Hsun Yeh, Hsinchu (TW); Yuh-Sheng Jean, Hsinchu (TW); Chi-Shun Weng, Hsinchu (TW)

(21) Appl. No.: 14/330,250

(22) Filed: Jul. 14, 2014

(30) Foreign Application Priority Data
Aug. 1, 2013 (TW) 102127684

(51) Int. Cl. G01R 31/26

(52) U.S. Cl. CPC G01R 31/2642
USPC 324/762.01

(57) ABSTRACT

The present invention discloses a circuit lifetime measuring device to estimate the rest lifetime of a target circuit, comprising: a reference clock receiving end for receiving a reference clock; a correlation signal generating circuit for providing a correlation signal in which at least some operating settings of the correlation signal generating circuit and the target circuit vary synchronously; a storage circuit for storing an initial relation between the reference clock and the correlation signal; a measuring circuit, coupled to the reference clock receiving end and the correlation signal generating circuit, for measuring a present relation between the reference clock and the correlation signal; and an estimating circuit, coupled to the storage circuit and the measuring circuit, for generating an estimation value according to the initial relation and the present relation, wherein the estimation value indicates the rest lifetime of the target circuit.

### BACKGROUND OF THE INVENTION

1. Field of the Invention

The present invention relates to a measuring device and method, especially to a circuit lifetime measuring device and method.

2. Description of Related Art

The lifetime (a.k.a. service life) of a general electronic circuit (e.g. an integrated circuit) is usually dependent on its operating settings. Under normal operating settings, an integrated circuit has a normal lifetime; however, sometimes a user tends to adjust the operating settings of the integrated circuit to pursue higher performance, and therefore the lifetime of the integrated circuit will be shortened. For many cases, a user may enhance the performance (e.g. the processing speed) of an integrated circuit by raising its operating voltage and/or frequency. Consequently, the closer the operating settings come to the limit and/or the longer the integrated circuit keeps at an overload status, the more the lifetime of the integrated circuit decreases. Although a reliability analysis may be adopted during the manufacturing process of an integrated circuit for measuring the normal lifetime of the integrated circuit, user's inclination in running the integrated circuit is still unpredictable, which means that the actual lifetime of the integrated circuit may be greatly different from user's expectation, that is to say the normal lifetime.

### SUMMARY OF THE INVENTION

In view of the problem of the prior art, an object of the present invention is to provide a circuit lifetime measuring device and a circuit lifetime measuring method which are capable of measuring the rest lifetime of a target circuit for one taking countermeasures.

The present invention discloses a circuit lifetime measuring device operable to measure the rest lifetime of a target circuit. An embodiment of the circuit lifetime measuring device comprises: a correlation signal generating circuit for providing a correlation signal in which at least some operating settings of the correlation signal generating circuit and a target circuit vary correspondingly; a storage circuit for storing an initial relation between a reference clock and the correlation signal; a measuring circuit coupled to the correlation signal generating circuit for measuring a present relation between the reference clock and the correlation signal; and an estimating circuit coupled to the storage circuit and the measuring circuit for generating an estimation value according to the initial relation and the present relation, wherein the estimation value indicates the rest lifetime of the target circuit.

In the above embodiment, the circuit lifetime measuring device may further comprise: a control circuit coupled to the estimating circuit for confining the variation range of the operating setting(s) of the target circuit according to the estimation value, so as to extend the rest lifetime of the target circuit or prevent it from getting worse.

The present invention also discloses a circuit lifetime measuring method which is carried out by the circuit lifetime measuring device of the present invention or the equivalent thereof and capable of measuring the rest lifetime of a target circuit. An embodiment of the circuit lifetime measuring method comprises the following steps: receiving a reference clock; providing a correlation signal by a correlation signal generating circuit in which at least some operating settings of the correlation signal generating circuit and a target circuit vary correspondingly; storing an initial relation between the reference clock and the correlation signal; measuring a present relation between the reference clock and the correlation signal; and generating an estimation value according to the initial relation and the present relation in which the estimation value indicates the rest lifetime of the target circuit.

In the above embodiment, the circuit lifetime measuring method may further comprise a step of confining the variation range of the operating setting(s) of the target circuit according to the estimation value, so as to extend the rest lifetime of the target circuit or prevent it from getting worse.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates an embodiment of the circuit lifetime measuring device of the present invention.

FIG. 2 illustrates another embodiment of the circuit lifetime measuring device of the present invention.

FIG. 3 illustrates an embodiment of the circuit lifetime measuring method of the present invention.

### DETAILED DESCRIPTION OF THE PREFERRED EMBODIMENTS

The following description uses language by referring to terms in the field of this invention. If any term is defined in the specification, such term should be explained accordingly. Besides, the connection between objects or events in the disclosed embodiments can be direct or indirect provided that these embodiments are still applicable under such connection. Said “indirect” means that an intermediate object or a physical space is existed between the objects, or an intermediate event or a time interval is existed between the events. Furthermore, this invention relates to circuit lifetime time measuring technique, and the known detail thereof will be omitted if such detail has little to do with the features of the present invention. Moreover, the shape, size, and scale of any element and the step sequence of any flow chart in the disclosed figures are just exemplary for understanding, not for limiting the scope of the present invention.

Additionally, each embodiment in the following description includes one or more features; however, this doesn't mean that one carrying out the present invention should make use of all the features of one embodiment at the same time, or should only carry out different embodiments separately. In other words, if an implementation derived from one or more of the embodiments is applicable, a person of ordinary skill in the art can selectively make use of some or all of the features in one embodiment or selectively make use of the combination of some or all features in several embodiments to have the implementation come true, so as to increase the flexibility in carrying out the present invention.

The present invention contains a circuit lifetime measuring device and a circuit lifetime measuring method capable of estimating the rest lifetime of a target circuit for automatic or manual adjustment to the operating setting(s) of the target circuit in accordance with the estimated rest lifetime, so that the service life of the target circuit could be extended or protected from getting worse. Said device and method are applicable to an integrated circuit or a system device, and people of ordinary skill in the art can choose components or steps equivalent to those described in this specification to carry out the present invention provided that these alternative implementations are workable. Besides, since some element by itself of the circuit lifetime measuring device of the present invention could be known, the detail of such element will be omitted provided that this omission nowhere dissatisfies the disclosure and enablement requirements. Similarly, since the circuit lifetime measuring method of the present invention can be carried out by the measuring device of the present invention or its equivalent, the following description will abridge the hardware details for executing the method but put the emphasis on the steps.

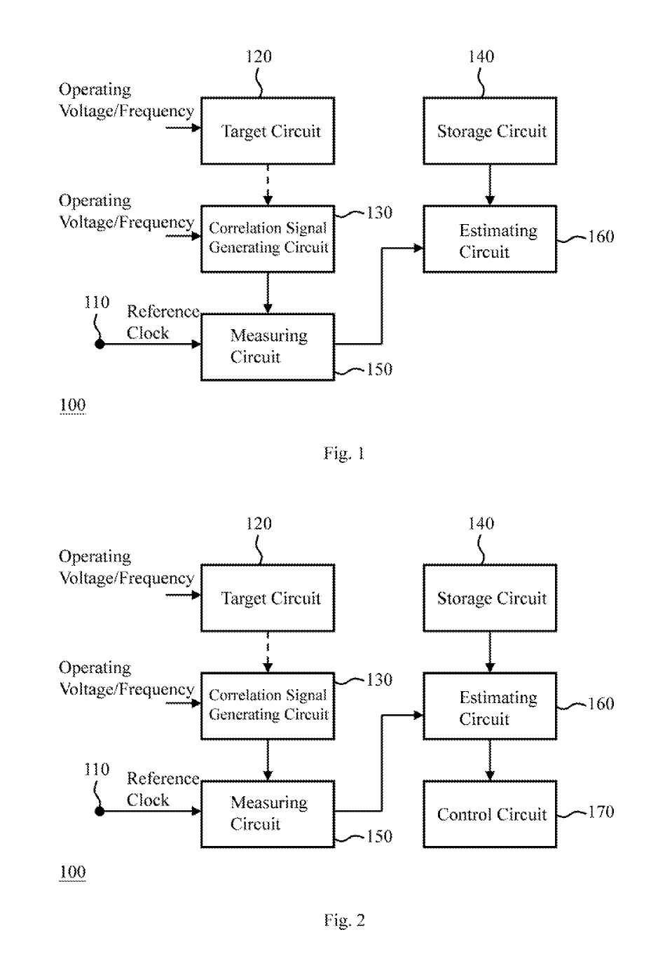

Please refer to FIG. 1 which illustrates an embodiment of the circuit lifetime measuring device of the present invention. The embodiment is able to estimate the rest lifetime of a target circuit and provide an estimation value for one applying countermeasures. Said target circuit can be an integrated circuit or a part (e.g. the part working at the highest speed) in the integrated circuit sensitive to the variation of some operating setting(s), and may be included in the circuit lifetime measuring device or independent of it. As shown in FIG. 1, the circuit lifetime measuring device 100 comprises: a reference clock receiving end 110; a correlation signal generating circuit 130; a storage circuit 140 (e.g. a non-volatile memory); a measuring circuit 150 (e.g. a counting circuit); and an estimating circuit 160. Said reference clock receiving end 110 is operable to receive a reference clock which is unrelated to the rest lifetime of a target circuit 120 or has negligible relation with it; therefore, the reference clock can be the basis for estimating the rest lifetime of the target circuit 120. In this embodiment, the reference clock is a semipermanent stable clock (e.g. the clock of crystal oscillator) or a clock (e.g. the clock of a phase locked loop) derived from the semipermanent stable clock. Said correlation signal generating circuit 130 is operable to provide a correlation signal, and has at least some operating setting(s) varying in response to the change of at least some operating setting(s) of the target circuit 120, which means that both the operating settings vary in a synchronous manner, a proportional manner or the like, so that the correlation signal is able to reflect the rest lifetime of the target circuit 120. For instance, when the operating voltage, operating frequency and/or operation times (or total amount of operation time or cycles) of the target circuit 120 climb up, the operating voltage, operating frequency and/or operation times (or total amount of operation time or cycles) of the correlation signal generating circuit 130 will climb up correspondingly; this indicates that if the status of the target circuit 120 degenerates, the status of the correlation signal generating circuit 130 will correspondingly degenerate, and therefore the correlation signal will reflect the degeneration status which is related to the rest lifetime of the target circuit 120. Said storage circuit 140 is operable to store an initial relation between the reference clock and the correlation signal, and the initial relation will be a reference ground for estimating the rest lifetime of the target circuit 120. For instance, the storage circuit 140 is operable to store a ratio of the initial reference clock period to the initial correlation signal period or the equivalent of the ratio to be the initial relation. Said measuring circuit 150 is coupled to the reference clock receiving end 110 and the correlation signal generating circuit 130, and operable to measure a present relation between the reference clock and the correlation signal and make the present relation a comparison ground for estimating the rest lifetime of the target circuit 120. For instance, the measuring circuit 150 is operable to measure a ratio of the present reference clock period to the present correlation signal period or the equivalent thereof to be the present relation. At last, said estimating circuit 160 is coupled to the storage circuit 140 and the measuring circuit 150, and operable to generate an estimation value in accordance with the mentioned initial relation and present relation. This estimation value indicates the rest lifetime of the target circuit 120 or the equivalent thereof, which means that the estimation value is related to or reflects the rest service life of the target circuit 120. For instance, the estimation value is the ratio of the present relation to the initial relation, or said ratio multiplied by a constant or variable coefficient, or said ratio multiplied by a predetermined value (e.g. a value in a pre-installed look-up table) in connection with this ratio, or some estimated value about the rest lifetime.

Please refer to FIG. 1 again. In this embodiment, the reference clock is generated through a reference clock generating circuit (not shown). This reference clock generating circuit may be included in the circuit lifetime measuring device 100 or independent of it. Besides, in an implementation of this embodiment, the correlation signal generating circuit 130 and the target circuit 120 work separately, which means that the operations of the two circuits 130, 120 are independent; however, their positions may be close to allow the correlation signal generating circuit 130 to reflect the status of the target circuit 120 more accurately. For instance, the correlation signal generating circuit 130 is a clock generating circuit (e.g. a ring oscillator), and operable to independently generate a clock signal as the correlation signal. Since at least some operating setting(s) of the clock generating circuit (i.e. the correlation signal generating circuit 130) and the target circuit 120 vary correspondingly (e.g. concurrently or proportionally), if the clock generating circuit works more frequently or stays under an overload state for more time as the target circuit 120 does, the clock frequency of the clock generating circuit will become slower and slower under such operating setting(s), which thereby reflects the current status (i.e. the rest lifetime) of the target circuit 120. Please note that the variation history of said clock frequency could be stored in a storage unit for the estimating circuit 160 performing the estimation accordingly. In another implementation of this embodiment, the correlation signal generating circuit 130 is coupled to the target circuit 120 (as indicated by the dotted arrow in FIG. 1), and operable to provide the correlation signal according to a signal of the target circuit 120. For instance, the correlation signal generating circuit 130 is a transmission path for outputting a signal of the target circuit 120 as the correlation signal to the measuring circuit 150; said signal could be a signal related to a speed of the target circuit 120 (such as a clock speed, a circuit operation speed, or a speed in connection with the delay time of a delay circuit). Besides, regarding the aforementioned storage circuit 140, it may further store a relative relation (e.g. a look-up table) between the signal of the target circuit 120 and the correlation signal in addition to the initial relation between the reference clock and the correlation signal; in this case, the estimating circuit 160 is operable to generating the estimation value according to the relative relation, the initial relation and the present relation. For instance, the relative relation is a constant ratio (e.g. 1:1), or a linear or non-linear relation which can be realized by a look-up table. More specifically, the estimating circuit 160 may generate the estimation value by having the ratio of the present relation to the initial relation multiplied by the constant ratio, or having the ratio of the present relation to the initial relation multiplied by a value of the look-up table in connection with that ratio.

Please refer to FIG. 2 which illustrates another embodiment of the circuit lifetime measuring device of the present invention. Compared with the embodiment of FIG. 1, this embodiment further comprises a control circuit 170 coupled to the estimating circuit 160 for confining the variation range of the concerned operating setting(s) or issuing a warning to remind users of stopping or easing overload operation of the target circuit 120 in light of the estimation value, which thereby extends the rest lifetime of the target circuit 120 or prevents it from getting worse. For instance, the control circuit 170 is a programmable logic circuit, a circuit including comparator(s), register(s) and/or logic gate(s), or a system composed of hardware and software, and operable to compare the estimation value with a threshold value, so as to reduce the variation range (e.g. the adjustable range of the operating voltage and/or frequency) of the concerned operating setting(s) available to users, lower the operating setting(s) (e.g. the operating voltage and/or frequency), and/or issue a warning to remind users of stopping or easing the overload operation when the estimation value reaches the threshold value; accordingly, the decreasing rate of the lifetime of the target circuit 120 will be relieved. More specifically, the threshold value could be a predetermined rest lifetime (e.g. 40% of the normal lifetime or 60% of the normal rest lifetime of the target circuit 120). When the estimation value exceeds the threshold value, the control circuit 170 will automatically reduce the available variation range of the operating setting(s) of the target circuit 120 (in which the variation range could be zero indicating that it is forbidden to override the target circuit 120), automatically lower the concerned operating setting(s) of the target circuit 120 to a predetermined normal setting or less, or issue an alert to remind users of the insufficient lifetime of the target circuit 120; so that the overload or strict operation of the target circuit 120 could be relieved or stopped. Said normal lifetime is usually a constant value (e.g. a value indicating 15 years lifetime) while the normal rest lifetime is a variable value (e.g. a value decreasing as the accumulated amount of operation time of the target circuit 120 goes up). Because the decision of these two values is not the feature of the present invention and those of ordinary skill in the art are able to make the decision on their own, the detail thereof will be omitted here.

Please note that in consideration of different designs, said estimation value may reach the threshold value from a low or a high. Besides, the control over the operating setting(s) such as the operating voltage and/or frequency of the target circuit 120 and the correlation signal generating circuit 130 may be realized through a power management circuit which could be integrated into the control circuit 170 or independent of it. Since a power management circuit and the function thereof is well-known in this filed, the detail thereof is therefore omitted. Please also note that the concrete values or circuit implementations alleged in the fore-disclosed embodiments are for understanding, not for limiting the scope of the present invention; in other words, people of ordinary skill in the art may derive values or implementations for completing the present invention by their own demand or design resources.

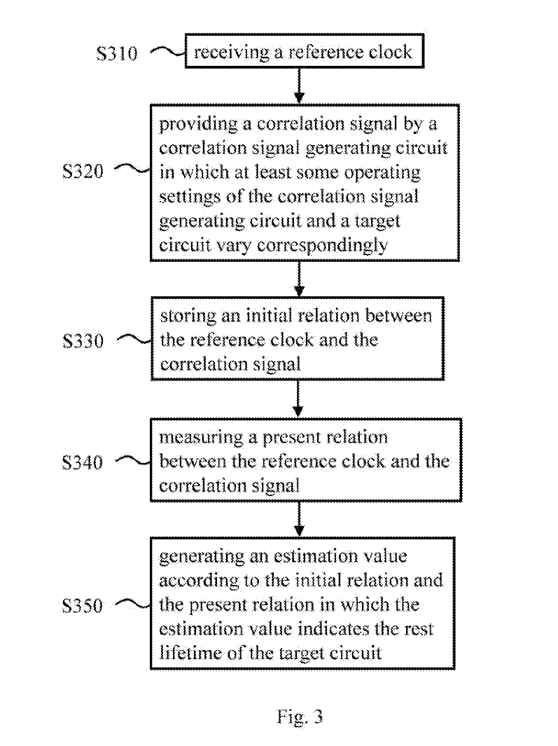

In addition to the above-discussed device invention, the present invention also discloses a circuit lifetime measuring method which can be carried out by the circuit lifetime measuring device of the present invention or the equivalent thereof. Similarly, this method is capable of estimating the rest lifetime of a target circuit and then providing an estimation value for a user or device to take countermeasures. Please refer to FIG. 3 which illustrates an embodiment of the circuit lifetime measuring method comprising the following steps:
Step S310: receiving a reference clock;
Step S320: providing a correlation signal by a correlation signal generating circuit in which at least some operating settings (e.g. operating voltage, operating frequency, and/or operation history such as operation times, total amount of operation time or cycles) of the correlation signal generating circuit and a target circuit vary correspondingly (e.g. synchronously or proportionally). In an implementation of this embodiment, the correlation signal is generated according to a signal of the target circuit; but in an alternative implementation of this embodiment, the correlation signal is independent of any signal of the target circuit.
Step S330: storing an initial relation between the reference clock and the correlation signal. For instance, the initial relation is a ratio of the initial period of the reference clock to the initial period of the correlation signal, or the equivalent thereof.
Step S340: measuring a present relation between the reference clock and the correlation signal. For instance, the present relation is a ratio of the present period of the reference clock to the present period of the correlation signal, or the equivalent thereof.
Step S350: generating an estimation value according to the initial relation and the present relation in which the estimation value indicates the rest lifetime of the target circuit. For instance, the estimation value could be the ratio of the present relation to the initial relation, or said ratio multiplied by a constant or variable coefficient, or said ratio multiplied by a predetermined value (e.g. a value from a look-up table) in connection with that ratio.

In light of the above, the present embodiment may further comprise the following step:
Step S335 (not shown): storing a relative relation between a signal of the target circuit and the aforementioned correlation signal in which the relative relation could be a constant ratio (e.g. a frequency ratio) or a linear or non-linear relation which could be stored and accessed by a look-up table. In this case, step S350 will generate said estimation value according to the relative relation, the initial relation and the present relation. For instance, step S350 has the ratio of the present relation to the initial relation multiplied by the said constant ratio to generate the estimation value, or has the ratio of the present relation to the initial relation multiplied by a value of a look-up table in connection with that ratio.

Besides, the embodiment of FIG. 3 may further comprise the following step:
Step S360 (not shown): confining the variation range of the concerned operating setting(s) according to the estimation value of step S350, so as to extend the rest lifetime of the target circuit or prevent it from getting worse. For instance, step S360 compares the estimation value with a threshold value, and then reduces the variation range of the concerned operating setting(s) (e.g. the adjustable range of the operating voltage and/or frequency) available to users and/or lowers the concerned operating setting(s) (e.g. the operating voltage and/or frequency) automatically when the estimation value satisfies the threshold value, so that step S360 is capable of relieving or stopping the overload operation of the target circuit.

Since people of ordinary skill in the art can fully appreciate the implementation and its modification of the method invention of FIG. 3 based on the description about the device invention of FIG. 1 and FIG. 2, the repeated and redundant description will be omitted provided that such omission has negligible influence for one understanding the method invention. Please note that the step sequence of the method invention is illustrative rather than restrictive, which means that the step sequence is alterable as long as the alteration to the method invention is still applicable.

In conclusion, the circuit lifetime measuring device and method of the present invention are capable of estimating the rest lifetime of a target circuit and automatically or manually adjusting the concerned operating setting(s) of the target circuit, and therefore the rest lifetime of the target circuit can be extended or prevented from getting worse. In brief, this invention can ensure the circuit lifetime of the target circuit while the influence of overload operation is taken into account.

The aforementioned descriptions represent merely the preferred embodiment of the present invention, without any intention to limit the scope of the present invention thereto. Various equivalent changes, alterations, or modifications based on the claims of present invention are all consequently viewed as being embraced by the scope of the present invention.

What is claimed is:

1. a circuit lifetime measuring device to estimate the rest lifetime of a target circuit, comprising:
a correlation signal generating circuit for providing a correlation signal in which at least some operating settings of the correlation signal generating circuit and the target circuit vary correspondingly;
a storage circuit for storing an initial relation between a reference clock and the correlation signal;
a measuring circuit, coupled to the correlation signal generating circuit, for measuring a present relation between the reference clock and the correlation signal; and
an estimating circuit, coupled to the storage circuit and the measuring circuit, for generating an estimation value according to the initial relation and the present relation, wherein the estimation value indicates the rest lifetime of the target circuit.

2. The circuit lifetime measuring device of claim 1, further comprising:
a reference clock generating circuit for providing the reference clock which is a crystal clock or an oscillation clock derived from the crystal clock.

3. The circuit lifetime measuring device of claim 1, wherein the correlation signal generating circuit is coupled to the target circuit and provides the correlation signal according to a signal of the target circuit.

4. The circuit lifetime measuring device of claim 1, wherein the correlation signal is independent of the target circuit.

5. The circuit lifetime measuring device of claim 4, wherein the correlation signal generating circuit is a clock generating circuit while the correlation signal is a clock signal.

6. The circuit lifetime measuring device of claim 1, wherein the at least some operating settings include an operating voltage and/or an operating frequency.

7. The circuit lifetime measuring device of claim 1, wherein the target circuit is integrated into the circuit lifetime measuring device.

8. The circuit lifetime measuring device of claim 7, wherein the circuit lifetime measuring device is an integrated circuit.

9. The circuit lifetime measuring device of claim 1, wherein the storage circuit further stores a relative relation between a signal of the target circuit and the correlation signal, and the estimating circuit generates the estimation value according to the relative relation, the initial relation and the present relation.

10. The circuit lifetime measuring device of claim 1, further comprising:
a control circuit, coupled to the estimating circuit, for confining the variation range of the operating settings in accordance with the estimation value.

11. The circuit lifetime measuring device of claim 10, wherein the control circuit compares the estimation value with a threshold value, and adjusts the variation range of the operating settings if the estimation value reaches the threshold value.

12. The circuit lifetime measuring device of claim 1, wherein the operating settings of the correlation signal generating circuit and the target circuit vary synchronously or proportionally.

13. A circuit lifetime measuring method, which is carried out by a circuit lifetime measuring device for measuring the rest lifetime of a target circuit, comprising the following steps:
receiving a reference clock;
providing a correlation signal by a correlation signal generating circuit in which at least some operating settings of the correlation signal generating circuit and the target circuit vary correspondingly;
storing an initial relation between the reference clock and the correlation signal;
measuring a present relation between the reference clock and the correlation signal; and
generating an estimation value according to the initial relation and the present relation in which the estimation value indicates the rest lifetime of the target circuit.

14. The circuit lifetime measuring method of claim 13, further comprising:
storing a relative relation between a signal of the target circuit and the correlation signal,
wherein the step of generating the estimation value includes: generating the estimation value according to the relative relation, the initial relation and the present relation.

15. The circuit lifetime measuring method of claim 13, further comprising:
confining the variation range of the operating settings according to the estimation value.

16. The circuit lifetime measuring method of claim 15, wherein the step of confining the variation range of the operating settings includes:
comparing the estimation value with a threshold value; and
reducing the variation range of the operating settings if the estimation value reaches the threshold value.

17. The circuit lifetime measuring method of claim 13, wherein the operating settings of the correlation signal generating circuit and the target circuit vary synchronously or proportionally.

18. The circuit lifetime measuring method of claim 13, wherein the correlation signal is independent of the target circuit.
